(19) United States
(12) Patent Application Publication
(10) Pub. No.: US 2014/0130842 A1
(43) Pub. Date: May 15, 2014

(54) BUSSING FOR PV-MODULE WITH UNEQUAL-EFFICIENCY BI-FACIAL PV-CELLS

(71) Applicant: PRISM SOLAR TECHNOLOGIES INCORPORATED, Highland, NY (US)

(72) Inventors: Jose E. Castillo-Aguilella, Tucson, AZ (US); Paul S. Hauser, Tucson, AZ (US); Wayne Beckerman, Stone Ridge, NY (US)

(73) Assignee: PRISM SOLAR TECHNOLOGIES INCORPORATED, Highland, NY (US)

(21) Appl. No.: 13/743,122

(22) Filed: Jan. 16, 2013

Related U.S. Application Data
(63) Continuation-in-part of application No. 13/676,173, filed on Nov. 14, 2012, now abandoned.
(60) Provisional application No. 61/728,645, filed on Nov. 20, 2012.

(51) Int. Cl. H01L 31/05

(52) U.S. Cl. CPC H01L 31/0504
USPC 136/246; 136/244; 136/251

(57) ABSTRACT

A PV module includes strings of serially electrically connected individual bifacial photovoltaic cells each of which is characterized by conversion efficiencies that are different for front and back sides of each cell. The module includes at least two of such strings which are electrically parallel to one another such that front sides of cells in one string and back sides of the cells in another string corresponding to the same side of the module. Each side of the module is thereby adapted to generate substantially the same amount of electrical power under otherwise equal circumstances. On a sunny day, the module generates as much electrical power before noon as after noon if the front side and the back side receive, aggregately, substantially the same amount of solar power incident thereon during the day.

### CROSS-REFERENCE TO RELATED APPLICATIONS

The present application is a continuation-in-part of U.S. patent application Ser. No. 13/676,173 filed on Nov. 14, 2012 and titled “Busses for Bifacial Photovoltaic Cells”, which in turn claims benefit of and priority from U.S. Provisional Patent Applications Nos. 61/559,425 filed on Nov. 14, 2011 and titled “Advanced Bussing Options for Equal Efficiency Bifacial Cells”; 61/559,980 filed on Nov. 15, 2011 and titled “Flexible Crystalline PV Module Configurations; 61/560,381 filed on Nov. 16, 2011 and titled “Volume Hologram Replicator for Transmission Type Gratings”; and 61/562,654 filed on Nov. 22, 2011 and titled “Linear Scan Modification to Step and Repeat Holographic Replicator”. The present invention also claims priority from the U. S. Provisional Patent Application No. 61/728,645 filed on Nov. 20, 2012 and titled “Redundant Bussing for PV Module with Unequal Efficiency PV Cells”. The disclosure of each of the abovementioned patent applications is incorporated herein by reference in its entirety.

### TECHNICAL FIELD

The present invention relates generally to conversion of solar energy to electrical energy. More particularly, the present invention relates to ways of operably cooperating of bifacial photovoltaic (PV) cells, the sides of which have unequal solar-energy-to-electricity conversion efficiency, to form a module in which both sides have substantially equal conversion efficiency.

### BACKGROUND OF THE INVENTION

Solar energy will satisfy an important part of future energy needs. While the need in solar energy output has grown dramatically in recent years, the total output from all solar installations worldwide still remains around 7 gigawatts, which is only a tiny fraction of the world's energy requirement. High material and manufacturing costs, low solar module efficiency, and shortage of refined silicon limit the scale of solar power development required to effectively compete with the use of coal and liquid fossil fuels.

The key issue currently faced by the solar industry is how to reduce system cost. The main-stream technologies that are being explored to improve the cost-per-kilowatt of solar power are directed to (i) improving the efficiency of solar cells that are part of solar modules, and (ii) delivering greater amounts of solar radiation onto the solar cell. In particular, these technologies include developing thin-film, polymer, and dye-sensitized photovoltaic (PV) cells to replace expensive semiconductor material based solar cells, the use high-efficiency smaller-area photovoltaic devices, and implementation of low-cost collectors and concentrators of solar energy.

While the reduction of use of semiconductor-based solar cells is showing great promise, for example, in central power station applications, challenges for the use of conventional solar cells remain for residential applications due to the form factor and significantly higher initial costs. Indeed, today's residential solar arrays are typically fabricated with silicon photovoltaic cells, and the silicon material constitutes the major cost of the module. Therefore techniques that can reduce the amount of silicon used in the module without reducing output power will lower the cost of the modules.

The use of devices adapted to concentrate solar radiation on a solar cell is one of such techniques. Various light concentrators have been disclosed in related art, for example a compound parabolic concentrator (CPC); a planar concentrator such as, for example, a holographic planar concentrator (HPC) including a planar highly transparent plate and a holographically-recorded optical element mounted on its surface; and a spectrum-splitting concentrator (SSC) that includes multiple, single-junction PV cells that are separately optimized for high efficiency operation in respectively-corresponding distinct spectral bands. A conventionally-used HPC is deficient in that the collection angle, within which the incident solar light is diffracted to illuminate the solar cell, is limited to about 45 degrees. Production of a typical SSC, on the other hand, requires the use of complex fabrication techniques.

Historically, PV cells have been monofacial, meaning that they have a single active surface capable of converting incident solar radiation to electric potential. Historically, monofacial solar cells are fabricated with a film stack including an anti-reflective/ hard coating optimized for transmittance at wavelengths for which silicon has the highest quantum efficiency, passivation, n doped and p doped silicon forming a single p-n junction, and a back electrode. Conventionally, the back electrode is a layer of metal such as aluminum. The front electrode is conventionally provided by a layer of transparent conductive material such as Indium Tin Oxide (ITO) in contact with a higher conductivity small area electrode made of Al, Ag, or some other metal or alloy. Since each conventional monofacial solar cell generates about 0.5V under illumination, conventional monofacial solar cells are typically arranged in electrical series, with the back electrode of a first cell electrically coupled to the front electrode of a second (i.e., adjacent) cell (or vice-versa). This series connection is repeated until the desired voltage is obtained.

Relatively recently, bifacial solar cells have been fabricated, which have photovoltaically active regions on both the front and back sides. Certain conventional bifacial solar cells are fabricated as an n+-p-p+stack between front and back electrodes. Other configurations are possible, so long as there are two junction regions proximate to a front active surface and back active surface, where each junction region forms an electron-hole pair. The front and back electrodes are conventionally fabricated from a transparent conductor—in general, a transparent conducting oxide such as, for example, ITO or AZO—in electrical contact with small area metal electrode (i.e., a bus bar or finger). Historically bifacial solar cells have had unequal efficiency between the front and back sides of the cells. Accordingly, conventional individual bifacial cells, when assembled into panels or series, are all oriented such that the “front” or high efficiency side is oriented to intercept direct sunlight, while the lower efficiency or “back” side is oriented to receive indirect sunlight from scatter, reflection off the ground or mounting surface, for example. Such orientation and associated electrical connection between and among the cells does not allow to maximize the electrical energy output from the resulting panels for certain applications. PV modules or panels that take advantage of different orientation of and electrical connections among the individual bifacial PV cells is, therefore, required.

### SUMMARY OF THE INVENTION

Embodiments of the invention provide a solar module having front and back sides and including at least two first strings each of which includes unequal efficiency bifacial PV cells (UEB cells) electrically connected in series such that each of the cells in a first string has one side with a first conversion efficiency and an opposite side with a second conversion efficiency, the second conversion efficiency being smaller than the first conversion efficiency, wherein all UEB cells in the first string have corresponding sides with the first conversion efficiency face in a chosen direction. The solar module also includes at least two second strings each of which contains the UEB cells electrically connected in series such that corresponding sides of the UEB cells with the second conversion efficiency face in the same chosen direction. In such module, at least one of the at least two first strings and at least one of the at least two second strings are electrically connected in parallel. An embodiment of the invention may be characterized by the two of the at least two first strings being electrically connected in series to form an upper string of UBE cells, and the two of the at least two second strings being electrically connected in series to form a lower string of UBE cells, and having the upper and lower strings of UEB cells electrically connected in parallel. In a related embodiment, the first string is electrically connected in parallel with the second string to form a parallel unit of UEB strings, and wherein at least two parallel units of UEB strings are electrically connected in series. A number of sides of UEB cells characterized by the first conversion efficiency and facing in the first direction may be equal to a number of sides of UEB cells characterized by the second conversion efficiency and facing in the first direction. Alternatively or in addition, all sides of the UEB cells corresponding to the front side of the module are substantially coplanar.

In one embodiment, the solar module additionally comprises first and second lites of glass disposed in a parallel and spaced-apart relationship to form a gap there between, and the at least two first strings and the at least two second strings are located in the gap, while a peripheral ring of sealing material is disposed around a perimeter of the module to sealably connect the first and second lites of glass while the module is structured to be devoid of a substantially rigid housing juxtaposed with at least one of the first and second lites of glass. In one implementation, the solar module is structured such that a curve, representing time-dependence of electrical power generated by the module, is substantially symmetric with respect to a time-point substantially corresponding to noon. Specifically, a portion of the curve corresponding to electrical power generation before noon is substantially symmetric to a portion of the curve corresponding to electrical power generation after noon when the front and back sides of the spatially-fixed module receive substantially equal amounts of solar energy. Substantially equal amounts of solar energy should be received by the front and back sides of the module before noon and after noon independently from illumination conditions. In one embodiment, however, such substantially equal amounts of solar energy are received on a sunny day.

Embodiments additionally include a solar module having a front side and a back side and containing two first strings of electrical elements, each of which includes UEB cells electrically connected in series, each of the cells in a first string having one side with a first conversion efficiency and an opposite side with a second conversion efficiency, the second conversion efficiency being smaller than the first conversion efficiency, wherein all UEB cells in the first string have corresponding sides with the first conversion efficiency face in a first direction. Such module additionally contains two second strings of electrical elements each of which includes the UEB cells electrically connected in series such that corresponding sides of the UEB cells with the second conversion efficiency face in the same first direction; and first and second lites of glass disposed in a parallel and spaced-apart relationship to form a gap there between, the two first strings and the two second strings located in the gap; and a peripheral ring of sealing material sealably connecting the first and second lites of glass around a perimeter of the module, while at least one of the two first strings and at least one the two second strings are electrically connected in parallel.

Any of the embodiments of the invention may additionally include a diffractive element (such as a holographically defined diffractive grating) in optical communication with at least one UEB cell. Embodiments may additionally include a flexible photovoltaic unit including first and second of the described solar modules and further comprising a flexible joint adjacently pliably connecting the first and second modules and an electrically-conductive member electrically a connecting UEB cell of the first solar module with an UEB cell of the second module, while the member passes through the flexible joint.

### BRIEF DESCRIPTION OF THE DRAWINGS

FIGS. 1A and 1B are diagrams showing, in front and rear views, a PV module including four strings of bifacial PV cells operably connected in series, string fashion with the identified facet of each of the PV cells aligned on the same side of the module;

FIGS. 2A and 2B are diagrams showing, in front and rear views, a PV module including four strings of bifacial PV cells operably connected in a linear string of two parallel groups of PV cells with the identified facet of each of the PV cells aligned on the same side of the module;

FIGS. 3A and 3B are diagrams showing, in front and rear views, a PV module including a parallel arrangement of two series each of which contains two strings of bifacial PV cells with the identified facet of each of the PV cells aligned on the same side of the module;

FIGS. 4A and 4B are diagrams showing, in front and rear views, a PV module including, according to an embodiment of the invention, four strings of bifacial PV cells operably connected in a linear string of two parallel groups of PV cells with each of the parallel groups having strings identified by opposite facets of the PV cells contained therein;

FIGS. 5A and 5B are diagrams showing, in front and rear views, a PV module including, according to the embodiment of the invention, a parallel arrangement of two series each of which contains two strings of bifacial PV cells with each of the parallel groups having strings identified by opposite facets of the PV cells contained therein;

FIG. 6A provides illustration to positioning an embodiment of the invention in East-West vertical orientation. When so installed, the embodiment receives substantially equal amount of solar energy on each of its sides and produces substantially equal amount of electrical energy from each of its sides;

FIG. 6B shows plots showing computed time-dependence of electrical power generated by several vertically mounted PV modules;

FIGS. 7A and 7B are diagrams showing, in top and side views, an embodiment of the invention structured as a frameless module;

FIG. 8 is an electrical scheme substantially equivalent to the embodiment of FIGS. 1A, 1B;

FIG. 9 is an electrical scheme substantially equivalent to the embodiment of FIGS. 2A, 2B;

FIG. 10 is an electrical scheme substantially equivalent to the embodiment of FIGS. 3A, 3B;

FIG. 11 is an electrical scheme substantially equivalent to the embodiment of FIGS. 4A, 4B;

FIG. 12 is an electrical scheme substantially equivalent to the embodiment of FIGS. 5A, 5B.

FIG. 13 is a diagram illustrating electrical connection among cells comprising a portion of an embodiment of the invention.

### DETAILED DESCRIPTION

References throughout this specification to “one embodiment,” “an embodiment,” “a related embodiment,” or similar language mean that a particular feature, structure, or characteristic described in connection with the referred to “embodiment” is included in at least one embodiment of the present invention. Thus, appearances of the phrases “in one embodiment,” “in an embodiment,” and similar language throughout this specification may, but do not necessarily, all refer to the same embodiment. It is to be understood that no portion of disclosure, taken on its own and in possible connection with a figure, is intended to provide a complete description of all features of the invention.

In addition, the following disclosure may describe features of the invention with reference to corresponding drawings, in which like numbers represent the same or similar elements wherever possible. In the drawings, the depicted structural elements are generally not to scale, and certain components are enlarged relative to the other components for purposes of emphasis and understanding. It is to be understood that no single drawing is intended to support a complete description of all features of the invention. In other words, a given drawing is generally descriptive of only some, and generally not all, features of the invention. A given drawing and an associated portion of the disclosure containing a description referencing such drawing do not, generally, contain all elements of a particular view or all features that can be presented is this view, for purposes of simplifying the given drawing and discussion, and to direct the discussion to particular elements that are featured in this drawing. A skilled artisan will recognize that the invention may possibly be practiced without one or more of the specific features, elements, components, structures, details, or characteristics, or with the use of other methods, components, materials, and so forth. Therefore, although a particular detail of an embodiment of the invention may not be necessarily shown in each and every drawing describing such embodiment, the presence of this detail in the drawing may be implied unless the context of the description requires otherwise. In other instances, well known structures, details, materials, or operations may be not shown in a given drawing or described in detail to avoid obscuring aspects of an embodiment of the invention that are being discussed. Furthermore, the described single features, structures, or characteristics of the invention may be combined in any suitable manner in one or more further embodiments.

For example, to simplify a particular drawing of an electro-optical device of the invention not all coatings or layers (whether electrically conductive, reflective, or absorptive or other functional coatings such as alignment coatings or passivation coatings), electrical interconnections between or among various elements or coating layers, elements of structural support (such as holders, clips, supporting plates, or elements of housing, for example), or auxiliary devices (such as sensors, for example) may be depicted in a single drawing. It is understood, however, that practical implementations of discussed embodiments may contain some or all of these features and, therefore, such coatings, interconnections, structural support elements, or auxiliary devices are implied in a particular drawing, unless stated otherwise, as they may be required for proper operation of the particular embodiment.

Moreover, if the schematic flow chart diagram is included, it is generally set forth as a logical flow-chart diagram. As such, the depicted order and labeled steps of the logical flow are indicative of one embodiment of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow-chart diagrams, they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Without loss of generality, the order in which processing steps or particular methods occur may or may not strictly adhere to the order of the corresponding steps shown.

The invention as recited in claims appended to this disclosure is intended to be assessed in light of the disclosure as a whole, including features disclosed in prior art to which reference is made.

A “laminate” refers generally to a compound material fabricated through the union of two or more components, while a term “lamination” refers to a process of fabricating such a material. Within the meaning of the term “laminate,” the individual components may share a material composition, or not, and may undergo distinct forms of processing such as directional stretching, embossing, or coating. Examples of laminates using different materials include the application of a plastic film to a supporting material such as glass, or sealing a plastic layer between two supporting layers, where the supporting layers may include glass, plastic, or any other suitable material.

As broadly used and described herein, the reference to an electrode or layer as being “carried” on a surface of an element refers to both electrodes or layers that are disposed directly on the surface of an element or disposed on another coating, layer or layers that are disposed directly on the surface of the element.

A bifacial photovoltaic cell allows for harvesting of solar energy from both the front and the back sides of the cell substantially without changing the structure of the cell. Currently available bifacial solar cells, however, are known to generally have unequal efficiencies of solar energy conversion for the front and back sides of an individual PV cell. It is appreciated, when such unequal-efficiency bifacial PV cells (UEB-cells) are assembled into conventional panels or series such that the “front” or “first” sides (high efficiency sides) of all the cells are oriented to intercept direct sunlight, while the lower efficiency or “back” sides are oriented to receive sunlight delivered indirectly (from scatter, reflection off of the ground, or mounting surface, for example), the electrical energy output from the resulting PV panels or modules is not optimized for certain applications. Conventionally, the modules containing bifacial cells have been positioned with the side of a cell having higher efficiency facing south, to capture the maximum amount of direct solar radiation possible. Generally accepted orientation of mounting the PV modules implies orienting the PV cells as directly towards the sun as possible. Contrary to this common perception, a vertical (and, optionally, fixed) mount of an embodiment of the module according to the invention with the sides of the module facing East-West provides an operational benefit in that, in such case, both sides of the module are adapted for substantially equal electrical power production.

The electrical power P_{M} generated by a solar module and measured in Watts can be defined as:

P_{M}=V_{M}*I_{M} Eq. (1)

Here, V_{M} is the voltage generated by the module and I_{M} is the current generated by the module. Similarly, electrical power P_{C} generated by a single solar cell in the PV-module can be expressed as:

P_{c}=V_{c}*I_{c} Eq. (2)

where V_{C} and I_{C} are voltage and current associated with such single cell. The power conversion efficiency of the solar cell (η_{cell}) can be defined as the ratio of the electrical power that is produced by the solar cell to the radiant power that reaches that solar cell:

$${η}_{c} = \frac{{P}_{c}}{{P}_{inc}} = \frac{{V}_{c} * {I}_{c}}{{A}_{c} * E} \qquad Eq . ( 3 )$$

Here, P_{inc} is the incident radiant power that reaches the solar cell, E is the solar irradiance that reaches the cell and usually given in [W/m²]. E is multiplied by the area of the solar cell (A_{c}) to obtain the total radiant power that reaches the cell.

Assuming that a single solar cell is under linear operational conditions(i.e., the current generated by the cell is substantially proportional to the incident radiant power) and that the solar cell is fully “on”, the current I_{C} produced by the solar cell having the above-mentioned power conversion efficiency is found to be:

$${I}_{c} = {η}_{c} \frac{E * {A}_{c}}{{V}_{c}} \qquad Eq . ( 4 )$$

The voltage associated with the cell is generally dependent on the semiconductor material used in cell construction and doping characteristics of such material, and as a first approximation can be assumed to be substantially constant as long as the cell is maintained at a substantially constant temperature. For commonly used in PV cell construction crystalline/polycrystalline silicon, the V_{c} is in the range of about 0.45 V to about 0.5 V at operational conditions (while kept at maximum power point by an inverter of the corresponding electrical circuitry) for ˜25° C. The current generated by the solar cell varies substantially linearly both with the irradiance and the efficiency of the cell.

In the case of a bifacial solar cell, the voltage associated with the cell is assumed to be substantially constant and the cell current is then given by:

$${I}_{c} = {η}_{1} \frac{{E}_{F} * {A}_{c}}{{V}_{c}} + {η}_{2} \frac{{E}_{B} * {A}_{c}}{{V}_{c}} \qquad Eq . ( 5 )$$

As discussed above, the bifacial PV cell is assumed to have differential power conversion efficiencies at different sides. For the purposes of the following presentation, a bifacial cell is assigned the efficiency η₁ to the front of the cell (which front receives an irradiance equal to E_{F}), while the other (back) side of the cell is assigned the efficiency η₂ (and assumed to receive the irradiance E_{B}). The total current produced by the bifacial cell is the aggregate of the currents generated by each individual surface of the bifacial cell.

From basic circuit theory and first order principles it can be derived that, when several—for example, three (3)—solar cells are connected in series, the total voltage is an aggregate of the voltages associated with those cells (for example, V=V₁+V₂+V₃) while the total current of the series is equal for each of the cells (I=I₁=I₂=I₃). The current will be limited by the lowest value of current among the currents producible by the cells that form the series. If we assume V_{c}=V₁=V₂=V₃ and I_{c}=I₁=I₂=I₃, the power produced by the three-cell serial arrangement is given as P=3Vc*Ic.

On the other hand, when several solar cells are connected in parallel, the total voltage is equal to the voltage of each cell (for example, V=V₁=V₂=V₃) while the total current of the paralleled cells is equal to an aggregate of individual cells' currents (for example, I=I₁+I₂+I₃). The voltage of such parallel arrangement of cells is limited by the lowest value of voltage among the voltage values corresponding to the individual cell. If we assume V_{c}=V₁=V₂=V₃ and I_{c}=I₁=I₂=I₃, the power produced by this arrangement is still given as P=Vc*3Ic, same as the case when the 3 cells were placed in parallel.

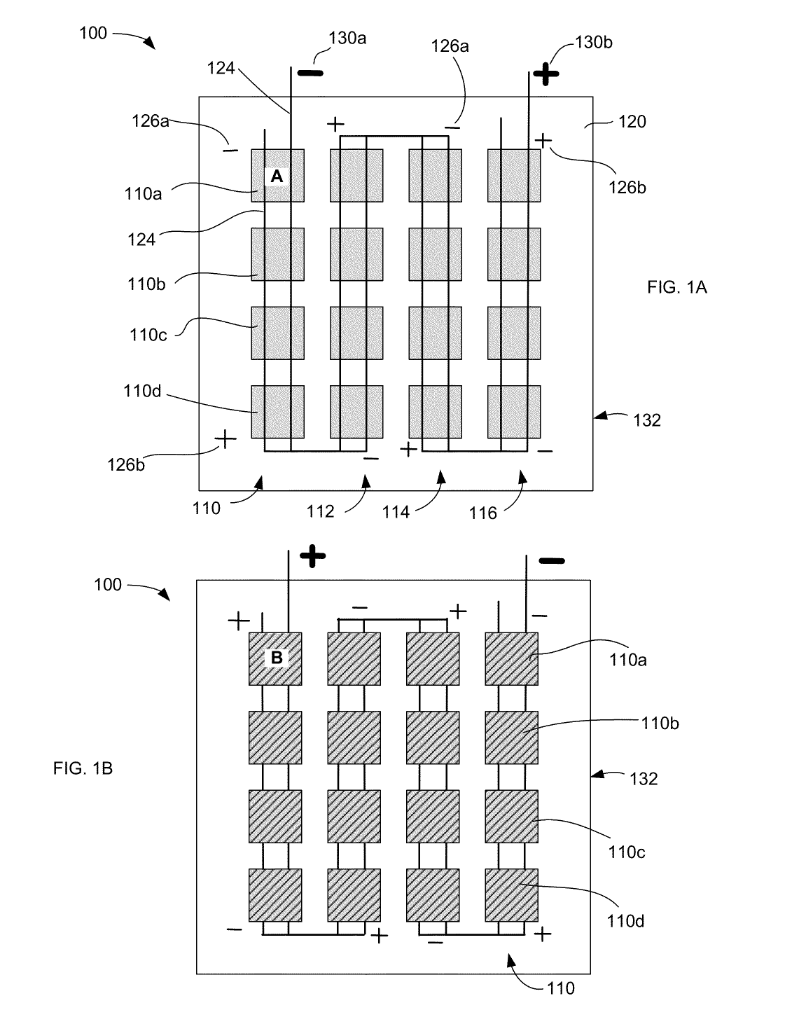

The following bussing busing options can be generally utilized:
The module that includes individual strings of PV cells that are, in turn, strung in series, thereby creating a PV module with one effective string. In a module in series, the current in the string is equal to the current of the cell with the lowest current, while the voltage of the string is the addition of all the individual cell voltages. If one cell in the string is “off” (producing very low or no current), as in the case of a shadowed cell, the whole string series is then off This arrangement is discussed below, for example, in reference to FIGS. 1A, 1B.
The module includes strings of PV cells that are arranged partially in series and partially in parallel. In a parallel system the voltage of the elements connected in parallel is equal, while the current of such paralleled elements is the aggregate of the currents produced by the individual paralleled elements.

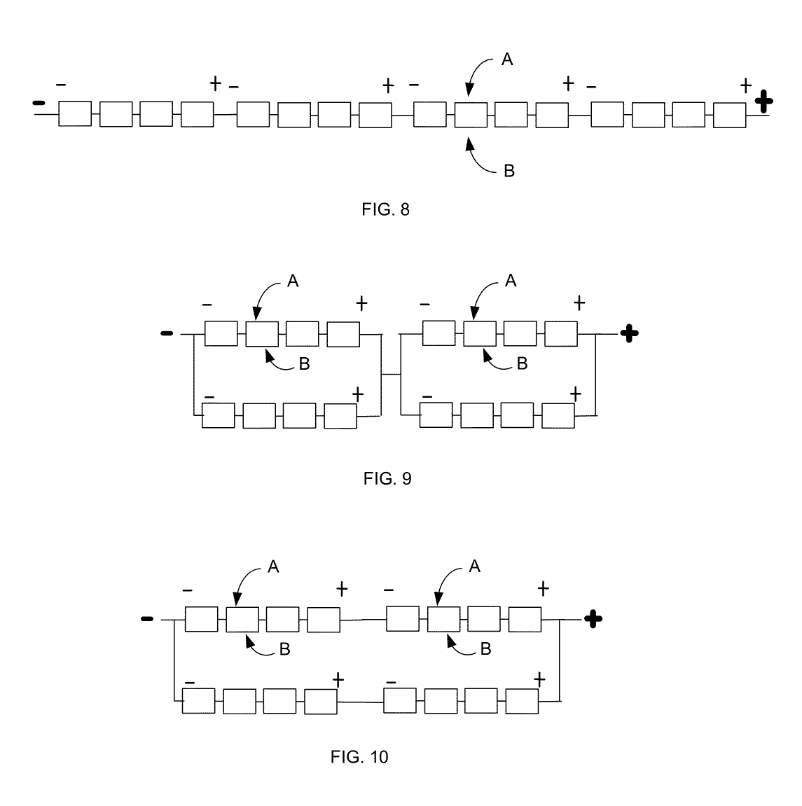

An example of a conventional implementation 100 of such UEB-cell-based PV module is illustrated schematically in FIGS. 1A and 1B. Here, the module 100 is shown in front and rear views as including four groups 110, 112, 114, and 116 of UEB-cells that are electrically connected to one another in a linear, serial fashion to form an overall string of sixteen UEB-cells. Spatial pattern-wise, these UEB-cells of the groups 110, 112, 114, and 116 are arranged in a form of a two-dimensional array juxtaposed with a supporting substrate 120 (such as a lite or plate of glass, for example). In reference to one group of the UEB-cells—for example, group 110—the individual cells 110a, 110b, 110c, 110d forming this group 110 are electrically connected in a linear and serial fashion with electrical buss(es) 124. The electrical polarity of an individual group of UEB-cells (such as the group 110, for example) is indicated with signs 126a, 126b (provided, in FIGS. 1A, 1B, outside the border 132 of the supporting substrate 120), while the overall electrical polarity of the resulting module 100 is shown with labels 130a, 130b (provided inside the border 132). Different sides of an individual UEB-cell are indicated with different hatching in front and rear views of FIGS. 1A, 1B. If a conversion efficiency of a “front” side of an UEB-cell is denoted “A” and the conversion efficiency of a “back” side of the UEB-cell is denoted “B”, then the arrangement of efficiency values corresponding to the front face of the module 100 shown in FIG. 1A can be described as a sequence of “AAAAAAAAAAAAAAAA”, with the same current passing through each of the individual UEB-cells of FIG. 1A. An electrical scheme equivalent to that of FIGS. 1A, 1B is presented in FIG. 8.

The power of the embodiment of FIGS. 1A, 1B is given by

$${P}_{M} = ( 16 {V}_{c} ) * [ {η}_{1} \frac{{E}_{F} * {A}_{c}}{{V}_{c}} + {η}_{2} \frac{{E}_{B} * {A}_{c}}{{V}_{c}} ] \qquad Eq . ( 6 )$$

The power from the front and back sides of the module 100 are associated with E_{F} and E_{B} respectively and, assuming that η₁≠η₂, the front and back sides of the module 100 produce different amounts of electrical power even when E_{F}=E_{B}.

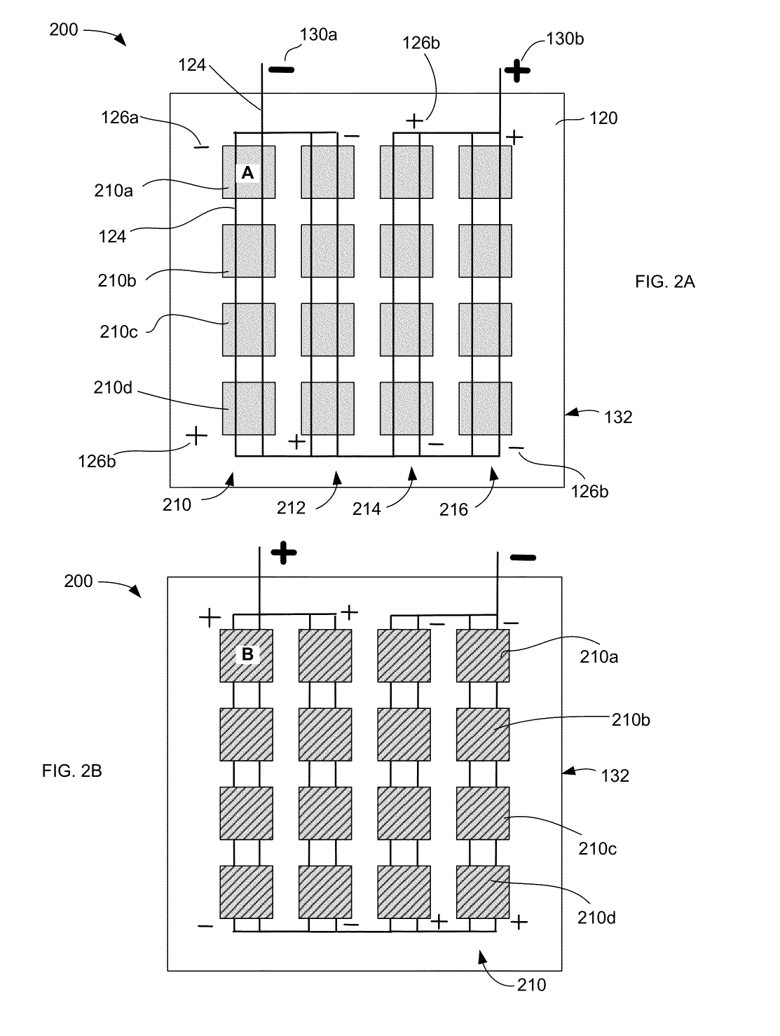

FIGS. 2A, 2B illustrate, in front and rear views, another implementation 200 of a PV module with groups 210, 212, 214, 216 of UEB-cells that are organized in two electrically-parallel pairs, which pairs in turn are electrically connected in a linear, serial fashion. The group 210 is shown to include serially connected individual UEB-cells 210a, 210b, 210c, 210d. The equivalent electrical scheme is shown in FIG. 9. In comparison with electrical characteristics of the embodiment 100, the voltage associated with the embodiment 200 is reduced by about a factor of two, while the current generated is substantially doubled.

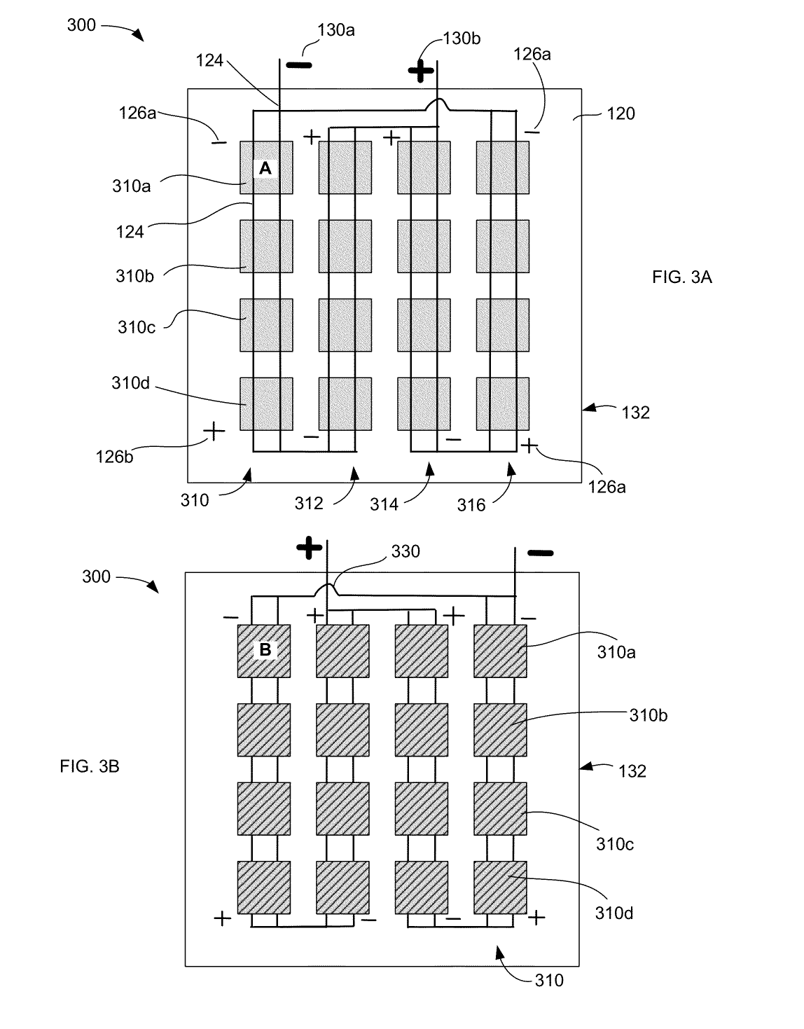

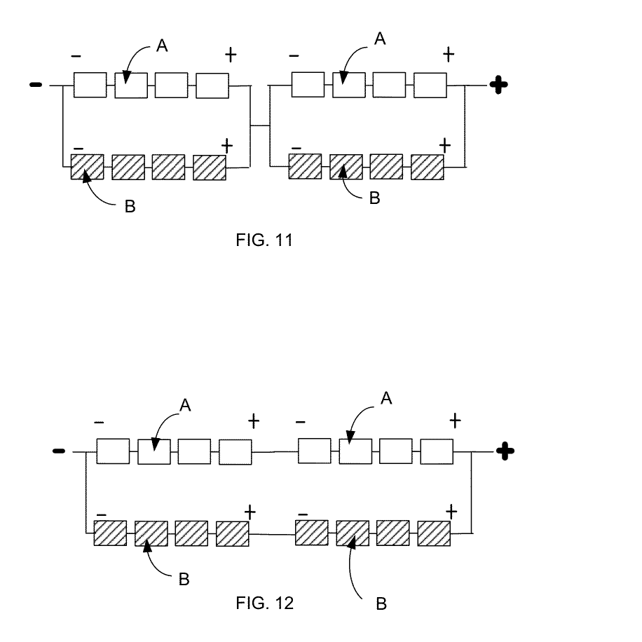

FIGS. 3A, 3B illustrate another PV module arrangement 300, in which groups 310, 312 of UEB-cells are organized in a first series, groups 314, 316 of UEB-cells are organized in a second series, and the first and second series are then electrically connected in parallel. The equivalent electrical scheme is shown in FIG. 10. In comparison with electrical characteristics of the embodiment 100 of FIGS. 1A, 1B, the voltage associated of the embodiment 300 is reduced in half, while the current draw is substantially doubled. The curve 300 in electrical traces of FIGS. 3A, 3B indicates the lack of electrical shortage and/or isolation between the traces that are shown as crossing each other.

The power produced by the module embodiments 200, 300 of FIGS. 2A, 2B and 3A, 3B is given by:

$${P}_{M} = ( 8 {V}_{c} ) * 2 [ {η}_{1} \frac{{E}_{F} * {A}_{c}}{{V}_{c}} + {η}_{2} \frac{{E}_{B} * {A}_{c}}{{V}_{c}} ] \qquad Eq . ( 7 )$$

The power received from the front and back sides of the modules 200, 300 are associated with E_{F} and E_{B} respectively and, provided that η₁≠η₂, the front and back sides produce different amounts of electrical power even when E_{F}=E_{B}.

It can be seen that the embodiments 100, 200, 300 produce equal amounts of the overall electrical power.

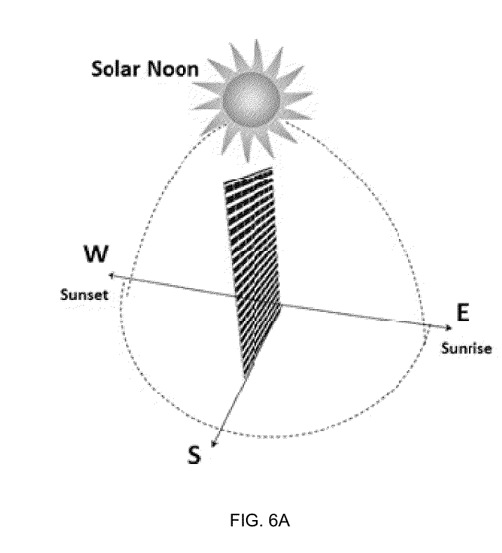

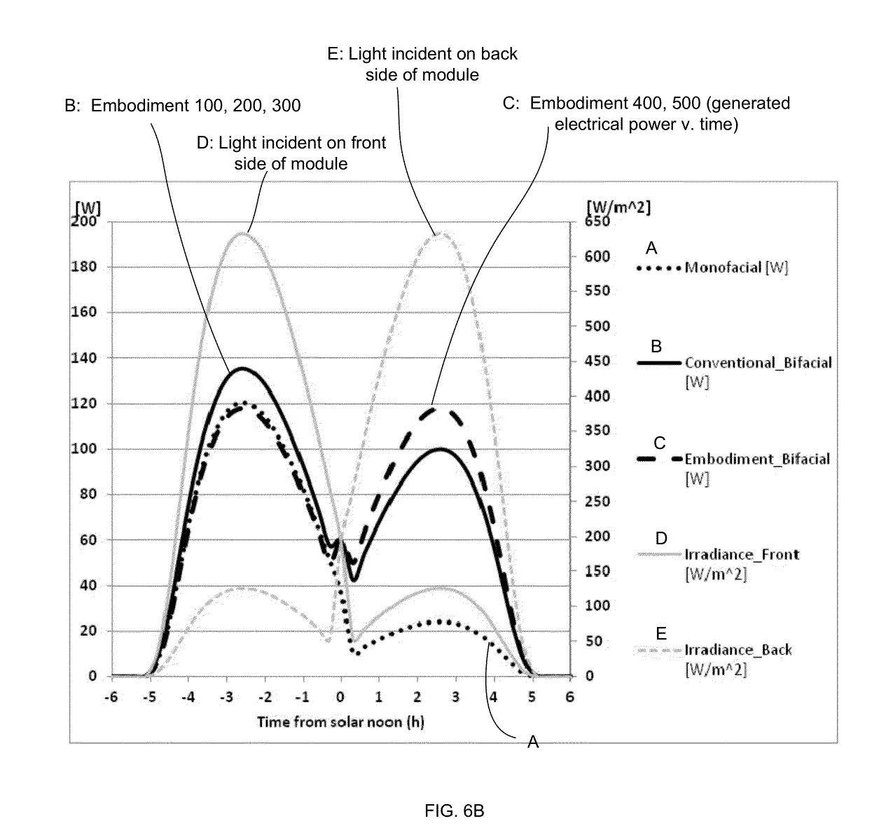

It is precisely such configurations that are used in fabrication of commercially-available PV modules or panels. Even through the cells are bifacial in nature, they are grouped together in the conventional manner with the sides having higher efficiency (for example, sides denoted in FIGS. 1A, 1B, 2A, 2B, 3A, 3B as “A”) aggregated on the same facet of the module, and with the sides having lower efficiency (for example, sides denoted in FIGS. 1A, 1B, 2A, 2B, 3A, 3B as “B”) aggregated on an opposite facet of the module. (Such PV cell arrangement proves to be non-optimal, operationally, substantially for any mounting orientation of the module. For the mounting orientation discussed below in reference to FIG. 6A, for example, a bifacial PV module of the related art would require a larger inverter, and therefore, added expense, than a module in which the PV cells and electrical wiring are optimized for equal conversion efficiency on each side of the module. For example, in one implementation, in order to produce the same amount of electrical power throughout the day as embodiments of the invention discussed below, which requires an invertor capable of handling about 120 W, a conventionally structured PV module with bifacial PV cells required an inverter capable of handling about 140 W).

The present application proposed a new PV-cell bussing modality, which balances strings of cells having of different solar-light-conversion efficiency, thereby achieving, in operation, substantially equal efficiency for both sides of the PV module. The proposed embodiments provide a more balanced energy production in certain PV-module applications such as applications employing east-west facing vertical PV walls, for example. Solar applications in which irradiation with reflected light and scattered light is to be preferred over direct irradiation by the sun, will also benefit from this wiring/busing modality.

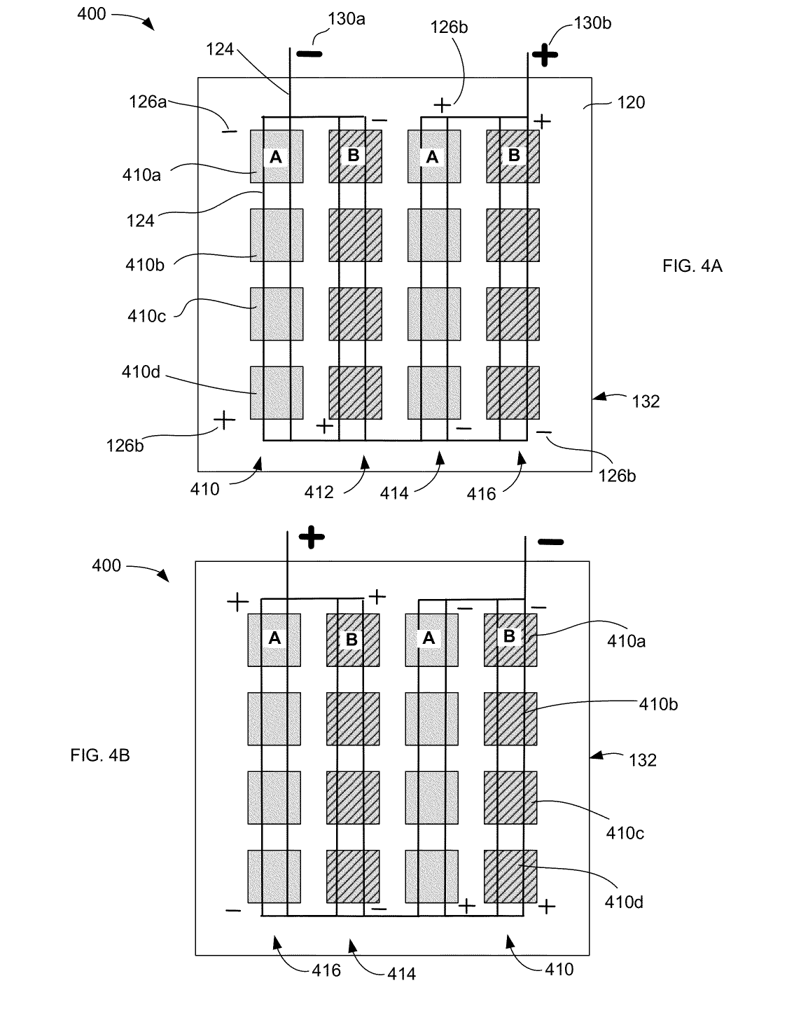

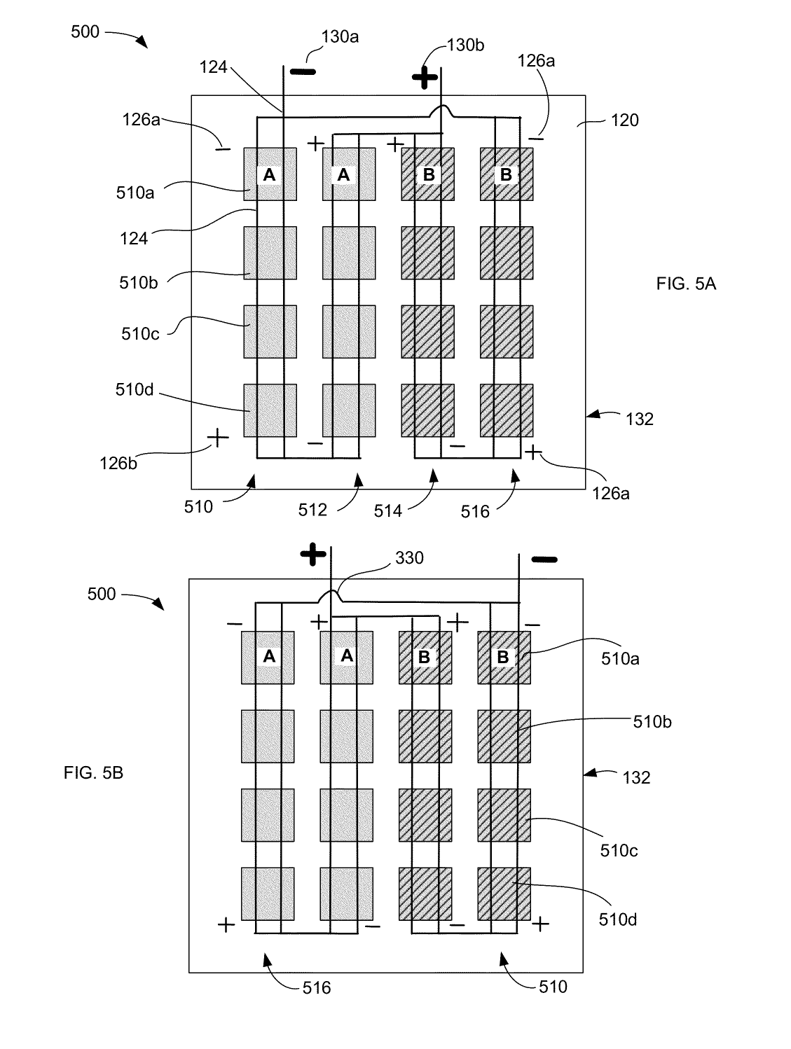

The idea of the present invention stems from the realization that enablement of the PV-module, that employs UEB-cells, to generate electrical power such that opposite facets or sides of the module produce substantially similar (under equal illumination conditions) amounts of power is industrially preferred in certain applications. According to the idea of the invention, such enablement can be achieved by electrically connecting the UEB-cells in a redundant fashion that includes having a first (electrically serial) string of bifacial PV cells electrically connected in parallel with a second (electrically serial) string of bifacial PV cells to form a facet of the PV module. In other words, a facet of the PV module includes individual bi-facial cells (or serially connected strings of bifacial cells) facing in one direction electrically arranged in parallel with individual cells (or serially connected strings of cells) facing in opposite direction. The parallel arrangement produces an averaging effect for the conversion efficiency for a given side of the PV module. (Since both sides, front and back, of the PV module now have approximately equal efficiency, in one embodiment the rear of the PV module may be defined as the side where the electrical junction box, j-box, is located.) FIGS. 4A, 4B, 5A, and 5B provide but two examples of embodiments of the invention. The j-box is not shown for simplicity of illustration.

FIGS. 4A, 4B illustrate schematically front and rear view of an embodiment 400 of the PV-module utilizing UEB-cells. As shown, the embodiment 400 employs four groups of UEB-cells: groups 410, 412, 414, and 416 (although a different number of cell-groups is within the scope of the invention and does not change the principle of structure and/or operation of an embodiment). In each group of the UEB-cells, a first facet of a cell, which is characterized by a first value of solar-power-to-electrical-power conversion efficiency, is denoted with “A” while an opposite (second) facet of the same cell, which is characterized by a second value of solar-power-to-electrical-power conversion efficiency, is denoted with “B”. (In a typical UEB-cell, generally, the first and second values of conversion efficiency are not equal to one another.) In addition, different sides of an UEB-cell are shown in a figure with different type of hatching. Two of the groups—as shown in FIG. 4A, groups 410, 414—have A-facets of corresponding UEB-cells aggregated at the front of the module 400, while the remaining two groups (groups 412, 416) have B-facets of corresponding UEB-cells associated with the front of the module 400. The groups 410, 412, 414, 416 of UEB-cells are organized in two electrically-parallel pairs (first pair including groups 410, 412; second pair including groups 414, 416) which pairs in turn are electrically connected in a linear, serial fashion. Each of the groups is shown to include electrically serially connected several individual UEB-cells. For example, the group 410 includes individual UEB-cells 410a, 410b, 410c, 410d. An electrical scheme equivalent to that of FIGS. 4A, 4B is presented in FIG. 11. The electrical voltage associated with the embodiment 400 is about a half of that associated with the embodiment 100 of FIGS. 1A, 1B while the electrical current is about doubled as compared with the embodiment 100.

FIGS. 5A, 5B illustrate an alternative embodiment 500 of the PV module according to the idea of the invention, in which groups 510, 512 of UEB-cells are connected sequentially in a first series, groups 514, 516 of UEB-cells are connected sequentially in a second series, and the first and second series are then electrically connected in parallel. Two of the groups—as shown in FIG. 5A, groups 510, 512—have A-facets of corresponding UEB-cells aggregated at the front of the module 500, while the remaining two groups (groups 514, 516) have B-facets of corresponding UEB-cells associated with the front of the module 400. An electrical scheme equivalent to that of FIGS. 5A, 5B is presented in FIG. 12. In comparison with electrical characteristics of the embodiment 100 of FIGS. 1A, 1B, electrical voltage associated with the embodiment 500 is reduced in half, while the generated current is substantially doubled. While the idea of the invention has been illustrated in reference to the embodiments 400, 500 each of which includes strings of UEB-cells, it is appreciated that in general an embodiment of the invention may include as few as two strings of serially connected UEB-cells, which strings are connected in parallel (see, for comparison, FIG. 12). In a specific embodiment, each of these two parallel strings can include a single UEB-cell.

The overall output electrical power produced by the embodiments 400, 500 is given by:

$${P}_{M} = ( 8 {V}_{c} ) * [ {η}_{1} \frac{{E}_{F} * {A}_{c}}{{V}_{c}} + {η}_{2} \frac{{E}_{F} * {A}_{c}}{{V}_{c}} + {η}_{2} \frac{{E}_{B} * {A}_{c}}{{V}_{c}} + {η}_{1} \frac{{E}_{B} * {A}_{c}}{{V}_{c}} ] \qquad Eq . ( 8 )$$

The electrical powers produced, individually, by the front and back sides of each of the modules 400, 500 are associated with E_{F} and E_{B}, respectively. Even though η₁≠η₂ and assuming that E_{F}=E_{B} are equal, the front and back sides of the modules 400 produce the same amount of electrical power. The same holds true for the embodiment 500.

While only one glass (or transparent plastic) substrate 120 is shown in either of the embodiments 400, 500, it is appreciated that, generally, UEB-cells are sandwiched (and, optionally, encapsulated with appropriate encapsulating material) between two transparent substrates disposed in a substantially parallel and spaced-apart relationship to form a gap there between (in which the arrays of UEB-cells are located). In order to protect the UEB-cell-containing environment of the gap from the external influence (such as ambient moisture, for example), a peripheral seal may be optionally added along and, optionally, around the perimeter of the resulting unit. Such seal may be formed from a conforming elastic material that facilitates environment-caused changes in mutual positioning and/or dimensions of the unit (for example, the expansion of the components of the unit due to heat).

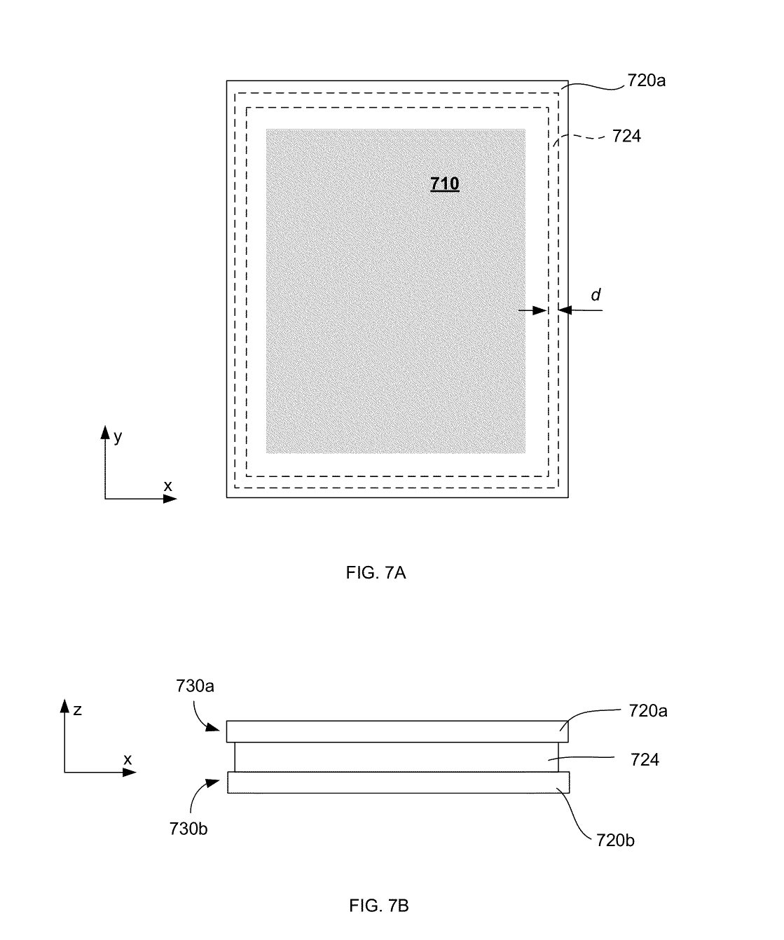

An example of the unit 700 is shown, in front and side views, in FIGS. 7A, 7B. Here, the compilation of UEB-cells and associated electrical busses (arranged according to the embodiments of the present invention, for example according to embodiments 400, 500), generally denoted with a shaded area 710, is disposed between the two substantially parallel lites of glass 720a, 720b that are sealingly affixed to one another with a perimeter seal 724 disposed between the lites 720a, 720b in a peripheral portion of the unit 700. The perimeter seal 724 may be optically opaque, translucent, or transparent and made of material such as, for example desiccated edge sealant. Generally, the perimeter seal 724 is shaped as a closed loop or ring with a width d sufficient to make the seal substantially impenetrable to the ambient atmosphere. In FIGS. 7A, 7B the seal 724 is shown to be disposed on the inboard side of the substrates 720a, 720b without reaching edges of the substrates (such as edges 730a, 730b, for example). In a related embodiment, however (not shown) the perimeter seal may be sized such that a dimensional extent of the seal is substantially equal to a dimensional extent of the PV module. For example, an overall width of the seal 724 may be substantially equal to the overall width of the unit 700 and/or an overall length of the seal 724 may be substantially equal to the overall length of the unit 700. In such an embodiment, the peripheral/perimeter seal 724 is disposed substantially “flush” with the edges of the module (such as edges 730a, 730b). The PV-module such as the module 700 is preferably devoid of any structural frame around the perimeter of the module. In a related embodiment, however, such frame made of metal or rigid plastic (that is structured to carry the weight of the module and to be mounted on and affixed to the chosen mounting site) can be present.

In further reference to the embodiments 400, 500, and 700, for the symmetry of the electrical connection scheme of the modules it is preferred that every group of UEB-cells of a module include the same number of individual UEB-cells and that all UEB-cells be of the same type. (Generally, however, arrangements of different types of UEB-cells and/or groups with unequal number of UEB-cells can be used to achieve the desired result and, therefore, are within the scope of the invention.)

PV modules employing bifacial cells (with unequal efficiency) structured according to the embodiments of the invention produce electrical power substantially “symmetrically” from either face of the module as long as each of the front and back sides receives substantially equal amount of solar energy. Such operational characteristic is advantageous in applications that have an “east-west” orientation of the PV modules or in which a higher relative contribution from the back is desired, such as the vertically mounted module shown in FIG. 6A.

It is appreciated that, when a PV module 400 or a PV-module 500 is disposed in a substantially vertical, east-west oriented position (i.e., with one facet of the module—for example, the front—facing the east and the opposite facet of the module facing the west), such module will generate electric power in a substantially temporally-symmetrical fashion in a course of the day. A schematic example of time-dependence of electrical power generation for so disposed PV module is presented in FIG. 6B. FIG. 6B presents plots for electrical power generated, throughout the day, by a conventional PV module employing monofacial PV cells, a conventional PV module employing bifacial PV cells (any of the embodiments 100, 200, 300), and any of the embodiments 400, 500 of the present invention structured with redundant bussing as described above. The modules were assumed to have an area of about 1 m², and mounted East-West. The simulation was carried out for an Equinox day, at 0 degrees latitude (at the Equator) and an albedo of 20% (defined by reflection of light from the ground). For the purposes of this disclosure, the term albedo is used to refer to a portion of incident light that is reflected overall (including both specular and diffuse reflection). Temperature-caused effects were not accounted for. The areas under the curves corresponding to each of the bifacial embodiments (100, 200, 300 or 400, 500) are substantially the same, thereby attesting that both wiring schemes generate substantially the same amount of energy throughout the day. [In further reference to FIG. 6B, as can be seen from the graphs, the UEB-cell arrangements conventionally structured PV modules generate electrical power during the first half of the day in a fashion that is substantially incongruent and non-conforming to the fashion of power generation during the second half of the day. As a result, the electrical power generation is not optimized throughout the day because the amount of power that can be drawn in the afternoon is substantially different from that in the morning. The time-dependent generation of electrical power by an embodiment of the invention before and after noon is, in contradistinction, substantially symmetric.]

In application where the embodiment 500 of the invention is disposed at an angle to the horizon (for example, when a PV module is conventionally racked, low tilt to latitude, on a white roof), the module 500 cold be rotated by about 90 degrees (as compared to the orientation in FIGS. 5A, 5B) such that the higher-efficiency cell facets (facets “A”) are arranged along the border of the module that is farthest from the roof, to increase the module's efficiency of collection of light reflected off of the roof. Proportionately, such rotated orientation increases the contribution of the rear face of the module to conversion of solar power as compared to the front face of the module.

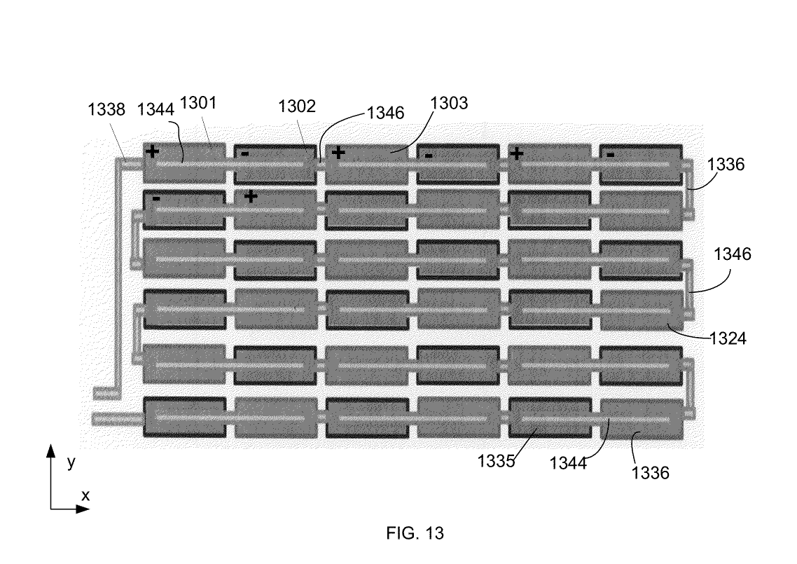

It is appreciated that structural arrangements of PV cells described above can be combined with bussing arrangements described in reference to FIG. 4 of the commonly assigned U.S. patent application Ser. No. 13/676,173 filed on Nov. 14, 2012 and incorporated herein in its entirety. Specifically, in a related embodiment, at least some of the PV cells can optionally be electrically connected according to a scheme depicted in FIG. 13 showing in a top plan view a two-dimensional array of bifacial solar cells mutually electrically coupled according to an embodiment of the invention. In this example embodiment 1300, thirty six (36) equal efficiency bifacial cells (e.g., 1301 through 1336) are provided. Each cell has positive and a negative face (which correspond to different sides of UEB-cells). For example, cell 1301 is oriented such that its positive face points “up” out of the xy-plane of FIG. 13. Similarly, cell 1302 is oriented such that its negative face points “up” out of the plane of FIG. 4. Individual cells of the embodiment 1300 are configured in a string with cells having alternate electrical polarity facing the same direction. Adjacent cells are electrically serially connected with bus bars. Because of the alternate polarity arrangement, bus bars are adapted to electrically connect adjacent cells in a front-to-front, and back-to-back manner, rather than in a conventional back-to-front manner of the related art. In the embodiment 1300, a bus bar 1344 connects the positive face of cell 1301 with the substantially co-planar negative face of adjacent cell 1302. The positive face cell 1302 is connected to the negative face of the adjacent cell 1303 in the string by a bus bar 1346, and so on, to result in a multiple serial connection of individual solar cells. The entire string of cells supplies its combined output current through bus bar 1348.

The invention has been described with reference to certain specific embodiments. Those skilled in the art of mine management and distributed computing systems generally may develop other embodiments of the present invention. The terms and expressions that have been used to describe certain embodiments in the foregoing specification are terms of description, rather than limitation, and, in using such terms, there is no intention to exclude equivalents of the features shown and described. Various configurations of individual PV cells (for example, cells including holograms), cooperation of PV modules in series of PV modules via flexible joints, and additional features of electrical connectors providing electrical communications between individual PV cells and/or individual PV modules of a series of the PV modules are discussed in above-mentioned patent applications incorporated herein by reference in their entirety. Examples of diffractive elements, methods of their fabrication, and related integration techniques are described, for example, in U.S. patent application Ser. No. 13/682,119 the entire disclosure of which is incorporated herein by reference. Examples of means to flexibly connect individual PV modules of the invention are discussed, for example, in U.S. patent application Ser. No. 13/675,855 the disclosure of which is incorporated herein by reference in its entirety. It should be apparent that modifications and adaptations to those embodiments may occur to one skilled in the art without departing from the scope of the present invention.

What is claimed is:

1. A solar module having a front side and a back side, the solar module comprising:
at least two first strings each including unequal efficiency bifacial PV cells (UEB cells) electrically connected in series, each of the cells in a first string having one side with a first conversion efficiency and an opposite side with a second conversion efficiency, the second conversion efficiency being smaller than the first conversion efficiency, wherein all UEB cells in a first string having corresponding sides with the first conversion efficiency face in a first direction;
at least two second strings each including the UEB cells electrically connected in series such that corresponding sides of the UEB cells with the second conversion efficiency face in the first direction;
wherein at least one of the at least two first strings and at least one of the at least two second strings are electrically connected in parallel.

2. A solar module according to claim 1, wherein the two of the at least two first strings are electrically connected in series to form an upper string of UBE cells, wherein the two of the at least two second strings are electrically connected in series to form a lower string of UBE cells, and wherein the upper and lower strings of UEB cells are electrically connected in parallel.

3. A solar module according to claim 1, wherein a first string is electrically connected in parallel with a second string to form a parallel unit of UEB strings, and wherein at least two parallel units of UEB strings are electrically connected in series.

4. A solar module according to claim 1, the operation of which is characterized by a curve, representing time-dependence of electrical power generated by the module on a sunny day, wherein a portion of the curve corresponding to electrical power generation before noon is substantially symmetric to a portion of the curve corresponding to electrical power generation after noon when the front and back sides of the spatially-fixed module receive substantially equal amounts of solar energy.

5. A solar module according to claim 1, further comprising a support module and juxtaposed with said module in such orientation that a first amount of electrical power generated by the module before noon is substantially equal to a second amount of electrical power generated by the module day after noon when the front and back sides of the spatially-fixed module receive substantially equal amounts of solar energy.

6. A solar module according to claim 1, wherein a number of sides of UEB cells characterized by the first conversion efficiency and facing in the first direction is equal to a number of sides of UEB cells characterized by the second conversion efficiency and facing in the first direction.

7. A solar module according to claim 1, wherein all sides of the UEB cells corresponding to the front side of the module are substantially coplanar.

8. A solar module according to claim 1, further comprising first and second lites of glass disposed in a parallel and spaced-apart relationship to form a gap there between, the at least two first strings and the at least two second strings located in the gap, and a peripheral ring of sealing material sealably connecting the first and second lites of glass around a perimeter of the module, said module being devoid of a substantially rigid housing juxtaposed with at least one of the first and second lites of glass.

9. A solar module according to claim 1, wherein said substantially rigid housing element is adapted to mount the module to a support.

10. A solar module according to claim 1, further comprising a diffractive element in optical communication with at least one UEB cell.

11. A flexible photovoltaic unit including first and second solar modules according to claim 1 and further comprising a flexible joint adjacently pliably connecting said first and second modules and an electrically-conductive member electrically a connecting UEB cell of the first solar module with an UEB cell of the second module, said member passing through the flexible joint.

12. A solar module having a front side and a back side, the solar module comprising:
two first strings each including unequal efficiency bifacial PV cells (UEB cells) electrically connected in series, each of the cells in a first string having one side with a first conversion efficiency and an opposite side with a second conversion efficiency, the second conversion efficiency being smaller than the first conversion efficiency, wherein all UEB cells in a first string having corresponding sides with the first conversion efficiency face in a first direction;
two second strings each including the UEB cells electrically connected in series such that corresponding sides of the UEB cells with the second conversion efficiency face in the first direction;
first and second lites of glass disposed in a parallel and spaced-apart relationship to form a gap there between, the two first strings and the two second strings located in the gap, and
a peripheral ring of sealing material sealably connecting the first and second lites of glass around a perimeter of the module,
wherein at least one of the two first strings and at least one the two second strings are electrically connected in parallel.

13. A solar module according to claim 12, further comprising a diffractive element in optical communication with at least one UEB cell.

14. A solar module according to claim 12, wherein the two first strings are electrically connected in series to form an upper string of UBE cells, wherein the two second strings are electrically connected in series to form a lower string of UBE cells, and wherein the upper and lower strings of UEB cells are electrically connected in parallel.

15. A solar module according to claim 12, wherein a first string is electrically connected in parallel with a second string to form a parallel unit of UEB strings, and wherein two parallel units of UEB strings are electrically connected in series.

16. A solar module according to claim 12, further comprising a support module and juxtaposed with said module in such orientation that a first amount of electrical power generated by the module on a sunny day before noon is substantially equal to a second amount of electrical power generated by the module on the sunny day after noon.
